(19) United States
(12) Patent Application Publication
(10) Pub. No.: US 2024/0321916 A1
(43) Pub. Date: Sep. 26, 2024

(54) IMAGING DEVICE

(71) Applicant: Panasonic Intellectual Property Management Co., Ltd., Osaka (JP)

(72) Inventors: SHUNSUKE ISONO, Osaka (JP); HIDENARI KANEHARA, Kyoto (JP); YUUKO TOMEKAWA, Osaka (JP)

(21) Appl. No.: 18/672,455

(22) Filed: May 23, 2024

Related U.S. Application Data
(63) Continuation of application No. PCT/JP2022/041782, filed on Nov. 9, 2022.

(30) Foreign Application Priority Data
Dec. 8, 2021 (JP) 2021-199024

(51) Int. Cl. H01L 27/146

(52) U.S. Cl. CPC H01L 27/14623; H01L 27/14636

(57) ABSTRACT

An imaging device includes a pixel section including pixels, a peripheral circuit section that is provided around the pixel section and that includes a peripheral circuit, and an intermediate layer that extends across the pixel section and the peripheral circuit section. The peripheral circuit section includes a light-shielding film located above the intermediate layer, at least one first conductive line that is located in the intermediate layer and that contains aluminum, and at least one barrier layer located between the at least one first conductive line and the light-shielding film.

### BACKGROUND

### 1. Technical Field

The present disclosure relates to an imaging device.

### 2. Description of the Related Art

An image sensor includes a photodetection element that generates an electrical signal in accordance with the intensity of incident light and includes a plurality of pixels arranged in one or two dimensions. A stacked image sensor is an image sensor that includes, as pixels, photodetection elements each having a structure in which a photoelectric conversion film is stacked on a substrate. An example of a stacked image sensor is described in Japanese Patent No. 4729275, Japanese Unexamined Patent Application Publication No. 2019-016667, Japanese Unexamined Patent Application Publication No. 2005-328068, Japanese Patent No. 5735318, and International Publication No. 2021/084971.

### SUMMARY

In one general aspect, the techniques disclosed here feature an imaging device including a pixel section including pixels, a peripheral circuit section that is provided around the pixel section and that includes a peripheral circuit, and an intermediate layer that extends across the pixel section and the peripheral circuit section. The peripheral circuit section includes a light-shielding film located above the intermediate layer, at least one first conductive line that is located in the intermediate layer and that contains aluminum, and at least one barrier layer located between the at least one first conductive line and the light-shielding film.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 illustrates the circuit configuration of an imaging device according to a first embodiment;

FIG. 2 is a cross-sectional view of the device structure of a pixel of the imaging device according to the first embodiment;

FIG. 3 is a plane view of the imaging device according to the first embodiment;

FIG. 4 is a cross-sectional view of the imaging device according to the first embodiment, taken along a line IV-IV of FIG. 3;

FIG. 5 is a cross-sectional view of an imaging device according to a comparative example;

FIG. 6 is a cross-sectional view of an imaging device according to a modification of the first embodiment;

FIG. 7 is a cross-sectional view of an imaging device according to a second embodiment; and

FIG. 8 is a cross-sectional view of an imaging device according to a third embodiment.

### DETAILED DESCRIPTIONS

In the image sensor described in International Publication No. 2021/084971, a light-shielding layer having a light shielding function and an electrical shielding function is formed so that transistors formed in the peripheral circuit section operate stably. The light-shielding layer covers a wiring layer over a wide area. In this case, the wiring layer may come into contact with the light-shielding layer due to, for example, a hillock or electromigration. If a short circuit occurs between the wiring layer and the light-shielding layer due to the contact, the potential of the light-shielding layer may vary, or a short circuit between the two wiring layers via the light-shielding layer may occur, resulting in unstable operation of the imaging device.

The present disclosure provides an imaging device capable of stabilizing the circuit operation.

### Outline of Disclosure

According to an aspect of the present disclosure, an imaging device includes a pixel section including pixels, a peripheral circuit section that is provided around the pixel section and that includes a peripheral circuit, and an intermediate layer that extends across the pixel section and the peripheral circuit section. The peripheral circuit section includes a light-shielding film located above the intermediate layer, at least one first conductive line that is located in the intermediate layer and that contains aluminum, and at least one barrier layer located between the at least one first conductive line and the light-shielding film. In other words, the light-shielding film is located at a higher position than the intermediate layer.

The aluminum-containing first conductive line has a low resistance and, thus, power supply to a circuit in the peripheral circuit section can be stabilized. Also, for example, the barrier layer blocks the growth of the irregularities on the surface of the first conductive line and, thus, the irregularities on the surface of the first conductive line are less likely to be brought into contact with the light-shielding film. Therefore, even if the light-shielding film has conducting properties, electrical connection between the light-shielding film and the first conductive line and between the first conductive lines via the light-shielding film can be avoided. As a result, the potential or the signal characteristics of the first conductive line can be maintained, and the circuit operation performed by the imaging device can be stabilized.

For example, the pixel section may include a photoelectric conversion film located above the intermediate layer and an upper electrode located above the photoelectric conversion film, and the peripheral circuit section may include a pad that supplies a potential to the upper electrode. In other words, the photoelectric conversion film is located at a higher position than the intermediate layer, and the upper electrode is located at a higher position than the photoelectric conversion film.

This allows the pad to be used to supply power to the upper electrode.

For example, the pad and the at least one first conductive line may be located in the same layer and be made of the same material.

This allows the pad and the first conductive line to be formed in the same process. Since the number of processes can be reduced, manufacturing variations, for example, can be reduced, and the reliability of the imaging device can be improved.

For example, the surface roughness Ra of each of the pad and the at least one first conductive line may be greater than or equal to 150 nm.

This allows the rough surface of the pad to make firm contact with a wire. As a result, the wire is prevented from falling off due to environmental changes and shocks and, thus, the power is stably supplied.

For example, the at least one barrier layer may contain a metal that is harder than aluminum and that has a melting point higher than the melting point of aluminum.

This effectively blocks aluminum growth due to hillocks or migration.

For example, the at least one barrier layer may have conducting properties.

This allows the use of metal as the material for the barrier layer, and the barrier layer can be formed in the same process as other electrode terminals and the like.

For example, the at least one first conductive line may include a plurality of first conductive lines, and the at least one barrier layer may include a plurality of barrier layers. The plurality of first conductive lines may be disposed so as to be separated from each other in plan view, and the plurality of barrier layers may be disposed so as to be separated from each other in plan view. Each of the plurality of barrier layers may be disposed so as to be aligned with a corresponding one of the plurality of first conductive lines.

This can prevent electrical connection between the first conductive lines via the barrier layer. For this reason, the potential or the signal characteristics of the first conductive line can be maintained, and the circuit operation performed by the imaging device can be stabilized.

For example, the at least one barrier layer may have insulation properties.

This can prevent electrical connection between the plurality of first conductive lines via the barrier layer.

For example, the film density of the at least one barrier layer may be higher than the film density of the intermediate layer.

This effectively blocks the growth of the irregularities on the surface of the first conductive line.

For example, the intermediate layer may include a tetraethyl orthosilicate film, and the at least one barrier layer may include an aluminum oxide film.

This allows, for example, a dense aluminum oxide film using the atomic layer deposition method to be used as a barrier layer. Because the same aluminum oxide film can be used to form a passivation film and the barrier layer in the pixel section, the number of processes can be reduced.

For example, the width of the at least one barrier layer may be equal to or greater than the width of the at least one first conductive line in plan view.

This allows, for example, the first conductive line to be completely covered by the barrier layer, thus blocking the growth of irregularities on the surface of the first conductive line.

For example, the imaging device according to the aspect of the present disclosure may further include a second conductive line that contains copper. The thickness of the at least one first conductive line may be greater than the thickness of the second conductive line.

This enables the film thicknesses of the first conductive line and pad to be increased. For example, when the thickness of the pad is large, damage caused by the impact of wire bonding can be reduced and, thus, the connection between the pad and a wire can be strengthened.

For example, the imaging device according to the aspect of the present disclosure may further include a substrate located below the intermediate layer. In other words, the substrate is located at a lower position than the intermediate layer. The distance between the light-shielding film and a surface of the substrate may be less than 5 μm.

Consequently, the distance between the substrate and the light-shielding film can be reduced and, thus, incidence of ambient light onto the impurity region provided on the substrate can be prevented by the light-shielding film. As a result, generation of leakage current and fluctuation of the electric potential within the substrate can be reduced, and the circuit operation can be stabilized.

For example, the at least one barrier layer may overlap the at least one first conductive line in plan view.

Consequently, the probability of contact of the irregularities of the surface on the first conductive line with the light-shielding film can be reduced more, since the barrier layer blocks the growth of the irregularities on the surface of the first conductive line.

For example, the peripheral circuit section may include a sample hold circuit, and the light-shielding film may overlap the sample hold circuit in plan view.

Consequently, the light-shielding film can prevent light from entering the sample hold circuit, thus reducing fluctuations in the amount of charge held in the sample hold circuit. As a result, deterioration of the image quality of an image generated by the imaging device can be reduced.

For example, the light-shielding film may cover the entirety of the at least one first conductive line.

For example, the pixel section need not include a conductive line that contains aluminum.

For example, the peripheral circuit section may further include a pad that differs from the at least one first conductive line.

For example, the pad may be provided in the same layer as the at least one first conductive line.

Exemplary embodiments are described in detail below with reference to the accompanying drawings.

Each of the embodiments described below is a comprehensive or particular example. A numerical value, a shape, a material, a constituent element, the positions and the connection form of the constituent elements, steps, and the sequence of steps described in the embodiments below are only examples and shall not be construed as limiting the scope of the present disclosure. In addition, among the constituent elements in the embodiments described below, the constituent element that does not appear in an independent claim is described as an optional constituent element.

In addition, all the drawings are schematic and not necessarily to scale. Therefore, for example, the scale and other details do not necessarily match in the drawings. The same reference numerals are used throughout the accompanying drawings to refer to substantially the same configurations, and duplicate descriptions may be eliminated or simplified.

As used herein, the terms describing the relationship between elements, such as “identical”, the terms describing the shape of an element, such as “rectangular”, and the terms describing a numerical range are not used in a strict sense but used in a broader sense (in a substantially equivalent range, for example, with a tolerance of several %).

As used herein, the terms “above”, “below”, “higher position” and “lower position” do not refer to the upward (vertical upward) position and downward (vertical downward) position, respectively, in absolute spatial perception but are used as terms defined by relative positional relationships based on the stacking order in the stacking configuration. In addition, the terms “above”, “below”, “higher position” and “lower position” are used not only when two constituent elements are disposed with a space therebetween and another constituent element is located therebetween but when two constituent elements are disposed in tight contact with each other.

### FIRST EMBODIMENT

### Circuit Configuration of Imaging Device

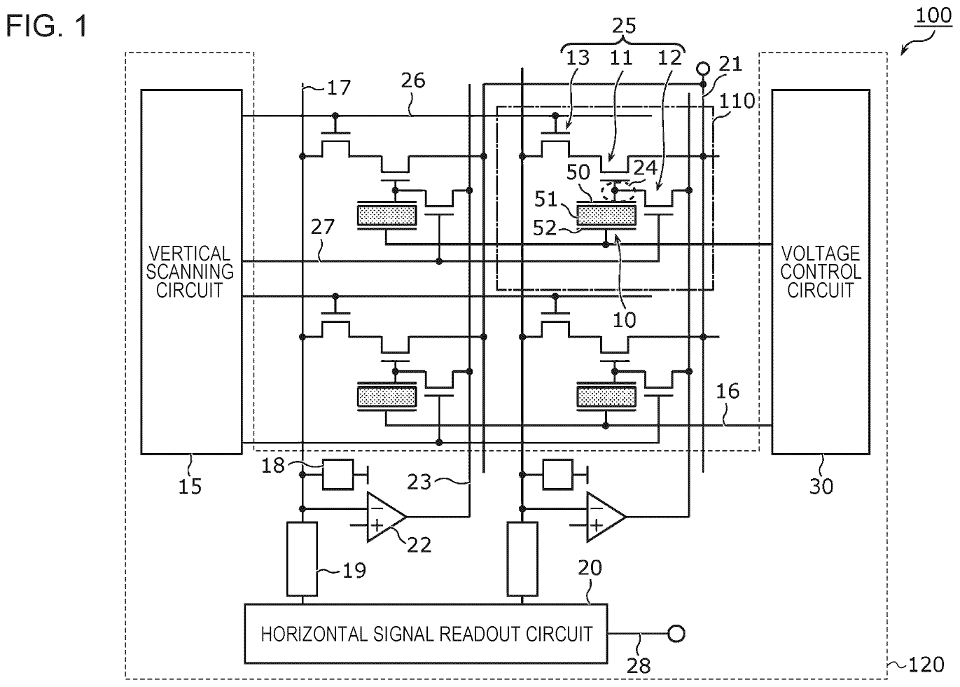

The circuit configuration of an imaging device according to the present embodiment is described first in a summarizing way with reference to FIG. 1.

FIG. 1 is a schematic illustration of the circuit configuration of an imaging device 100. As illustrated in FIG. 1, the imaging device 100 includes a plurality of pixels 110 and peripheral circuitry 120.

The plurality of pixels 110 are arranged on a semiconductor substrate in two dimensions, that is, in the row and column directions, to form a pixel region. The plurality of pixels 110 may be arranged in a single column. That is, the imaging device 100 may be a line image sensor. As used herein, the terms “row direction” and “column direction” refer to the directions in which the row and column extend, respectively. More specifically, the vertical direction is the column direction, and the horizontal direction is the row direction.

Each of the pixels 110 includes a photodetector 10 and a charge detection circuit 25. The photodetector 10 includes a pixel electrode 50, a photoelectric conversion film 51, and a transparent electrode 52. The particular configuration of the photodetector 10 is described below. The charge detection circuit 25 includes an amplifier transistor 11, a reset transistor 12, and an address transistor 13.

The imaging device 100 includes a voltage control element for applying a predetermined voltage to the transparent electrode 52. The voltage control element includes, for example, a voltage control circuit, a voltage generating circuit, such as a constant voltage source, and a voltage reference line, such as a ground line. The voltage applied by the voltage control element is referred to as a control voltage. According to the present embodiment, the imaging device 100 includes a voltage control circuit 30 serving as the voltage control element.

The voltage control circuit 30 may generate a constant control voltage or may generate a plurality of control voltages of different values. For example, the voltage control circuit 30 may generate control voltages of two or more different values or may generate a control voltage that varies continuously within a predetermined range. The voltage control circuit 30 determines the value of the control voltage to be generated on the basis of an instruction from an operator operating the imaging device 100 or an instruction from, for example, another control unit provided in the imaging device 100. Thereafter, the voltage control circuit 30 generates the control voltage of the determined value. The voltage control circuit 30 is provided outside of a photosensitive region as part of the peripheral circuitry 120. The photosensitive region is substantially the same as the pixel region.

According to the present embodiment, as illustrated in FIG. 1, the voltage control circuit 30 applies the control voltage to the transparent electrodes 52 of the pixels 110 arranged in the row direction via a counter electrode signal line 16. Thus, the voltage control circuit 30 changes the voltage between the pixel electrode 50 and the transparent electrode 52 and switches between the spectral response characteristics of the photodetector 10.

To accumulate electrons in the pixel electrode 50 as signal charge when the photodetector 10 is irradiated with light, the pixel electrode 50 is set to a higher potential than the transparent electrode 52. At this time, since the direction of movement of electrons is opposite to that of holes, a current flows from the pixel electrode 50 toward the transparent electrode 52. To accumulate holes in the pixel electrode 50 as signal charge when the photodetector 10 is irradiated with light, the pixel electrode 50 is set to a lower potential than the transparent electrode 52. At this time, a current flows from the transparent electrode 52 to the pixel electrode 50.

The pixel electrode 50 is connected to the gate electrode of the amplifier transistor 11, and the signal charge collected in pixel electrode 50 is accumulated in a charge storage node 24 that is located between the pixel electrode 50 and the gate electrode of the amplifier transistor 11. According to the present embodiment, the signal charge is holes. Alternatively, the signal charge may be electrons.

The signal charge accumulated in the charge storage node 24 is applied to the gate electrode of the amplifier transistor 11 as a voltage corresponding to the amount of signal charge. The amplifier transistor 11 is included in the charge detection circuit 25 and amplifies the voltage applied to the gate electrode. The address transistor 13 selectively reads out the amplified voltage as a signal voltage. The address transistor 13 is also referred to as a “row selection transistor 13”. One of the drain and the source of the reset transistor 12 is connected to the pixel electrode 50, and the reset transistor 12 resets the signal charge stored in the charge storage node 24. That is, the reset transistor 12 resets the potential of the gate electrode of the amplifier transistor 11 and the potential of the pixel electrode 50.

To selectively perform the operations described above in the plurality of pixels 110, the imaging device 100 includes a power supply conductive line 21, a vertical signal line 17, an address signal line 26, and a reset signal line 27. These conductive line and signal lines are connected to the pixel 110. More specifically, the power supply conductive line 21 is connected to one of the source and drain of the amplifier transistor 11. The vertical signal line 17 is connected to the other of the source and drain of the address transistor 13, that is, the one not connected to the amplifier transistor 11. The address signal line 26 is connected to the gate electrode of the address transistor 13. The reset signal line 27 is connected to the gate electrode of the reset transistor 12.

The peripheral circuitry 120 includes a vertical scanning circuit 15, a horizontal signal readout circuit 20, a plurality of column signal processing circuits 19, a plurality of load circuits 18, a plurality of differential amplifiers 22, and the voltage control circuit 30. The vertical scanning circuit 15 is also referred to as a “row scanning circuit 15”. The horizontal signal readout circuit 20 is also referred to as a “column scanning circuit 20”. The column signal processing circuit 19 is also referred to as a “row signal storage circuit 19”. The differential amplifier 22 is also referred to as a “feedback amplifier 22”.

The vertical scanning circuit 15 is connected to the address signal line 26 and the reset signal line 27. The vertical scanning circuit 15 selects the plurality of pixels 110 arranged in each row on a row basis, reads out the signal voltages, and resets the potential of the pixel electrode 50. The power supply conductive line 21 supplies a predetermined power supply voltage to each of the pixels 110. The horizontal signal readout circuit 20 is electrically connected to the plurality of column signal processing circuits 19. Each of the column signal processing circuits 19 is electrically connected to the pixels 110 in one of the columns via the vertical signal line 17 corresponding to the column. Each of the load circuits 18 is electrically connected to one of the vertical signal lines 17. The load circuit 18 and the amplifier transistor 11 form a source follower circuit.

Each of the plurality of differential amplifiers 22 is provided corresponding to one of the columns. A negative input terminal of the differential amplifier 22 is connected to the corresponding vertical signal line 17. An output terminal of the differential amplifier 22 is connected to the pixels 110 via the feedback line 23 corresponding to the column.

The vertical scanning circuit 15 applies a row selection signal, which controls the turning on and off of the address transistor 13, to the gate electrodes of the address transistors 13 by using the address signal line 26. As a result, the row to be read out is scanned and selected. The signal voltages are read out from the pixels 110 of the selected row to the vertical signal lines 17, respectively. The vertical scanning circuit 15 also applies a reset signal that controls the on and off of the reset transistor 12 to the gate electrodes of the reset transistors 12 via the reset signal line 27. This selects the row of pixels 110 subject to the reset operation. The vertical signal line 17 transmits the signal voltage read out from the pixel 110 selected by the vertical scanning circuit 15 to the column signal processing circuit 19.

The column signal processing circuit 19 performs, for example, noise suppression signal processing (typically, correlated double sampling) and analog-to-digital conversion (AD conversion). More specifically, the column signal processing circuit 19 includes a sample hold circuit. The sample hold circuit includes a capacitor and a transistor. The sample hold circuit samples and temporarily holds the signal voltage read out via the vertical signal line 17. A digital value corresponding to the held voltage value is read out by the horizontal signal readout circuit 20.

The horizontal signal readout circuit 20 sequentially reads the signals from the plurality of column signal processing circuits 19 and outputs the signals to a horizontal common signal line 28.

The differential amplifier 22 is connected to the other of the drain and source of the reset transistor 12, which is not connected to the pixel electrode 50, via the feedback line 23. Therefore, the differential amplifier 22 receives the output value of the address transistor 13 by the negative input terminal when the address transistor 13 and the reset transistor 12 are in a conducting state. The differential amplifier 22 performs a feedback operation so that the gate potential of the amplifier transistor 11 becomes a predetermined feedback voltage. At this time, the output voltage value of the differential amplifier 22 is 0 V or a positive voltage near 0 V. As used herein, the term “feedback voltage” refers to the output voltage of the differential amplifier 22.

### Pixel Structure

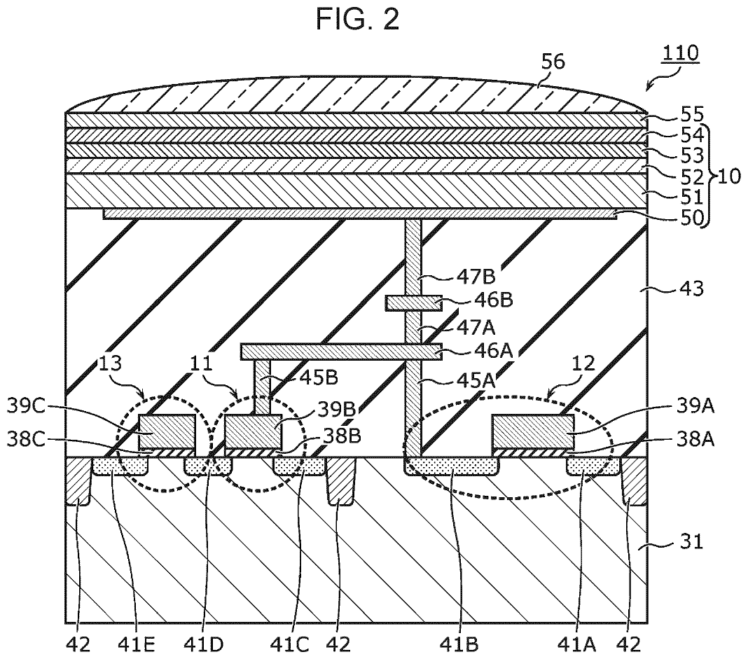

The device structure of the pixel 110 of the imaging device 100 is described in detail below with reference to FIG. 2. FIG. 2 is a schematic cross-sectional view of the device structure of the pixel 110 of the imaging device 100.

As illustrated in FIG. 2, the pixel 110 includes a semiconductor substrate 31, the charge detection circuit 25 (not illustrated), and the photodetector 10. The semiconductor substrate 31 is, for example, a p-type silicon substrate. The charge detection circuit 25 detects signal charge captured by the pixel electrode 50 and outputs a signal voltage. The charge detection circuit 25 includes the amplifier transistor 11, the reset transistor 12, and the address transistor 13. The charge detection circuit 25 is formed on the semiconductor substrate 31.

Each of the amplifier transistor 11, the reset transistor 12, and the address transistor 13 is an example of an electrical element formed on the semiconductor substrate 31. Each of the amplifier transistor 11, the reset transistor 12, and the address transistor 13 is, for example, a MOSFET (Metal Oxide Semiconductor Field Effect Transistor). More specifically, each of the amplifier transistor 11, the reset transistor 12, and the address transistor 13 is an n-channel MOSFET, but may be a p-channel MOSFET.

The amplifier transistor 11 has n-type impurity regions 41C and 41D, a gate insulating layer 38B, and a gate electrode 39B. The n-type impurity regions 41C and 41D are formed inside of the semiconductor substrate 31. Each of the n-type impurity regions 41C and 41D serves as a drain or a source. The gate insulating layer 38B is located on the semiconductor substrate 31. The gate electrode 39B is located on the gate insulating layer 38B.

The reset transistor 12 has n-type impurity regions 41A and 41B, a gate insulating layer 38A, and a gate electrode 39A. The n-type impurity regions 41A and 41B are formed inside of the semiconductor substrate 31. Each of the n-type impurity regions 41A and 41B serves as a drain or a source. The gate insulating layer 38A is located on the semiconductor substrate 31. The gate electrode 39A is located on the gate insulating layer 38A.

The address transistor 13 has n-type impurity regions 41D and 41E, a gate insulating layer 38C, and a gate electrode 39C. The n-type impurity regions 41D and 41E are formed inside of the semiconductor substrate 31. Each of the n-type impurity regions 41D and 41E serves as a drain or a source. The gate insulating layer 38C is located on the semiconductor substrate 31. The gate electrode 39C is located on the gate insulating layer 38C.

The gate insulating layers 38A, 38B, and 38C are formed using an insulating material. For example, the gate insulating layers 38A, 38B and 38C have a single-layer structure of a silicon oxide film or silicon nitride film or have a stacked structure of these films.

The gate electrodes 39A, 39B, and 39C are each formed using a conductive material. For example, the gate electrodes 39A, 39B, and 39C are formed using polysilicon having conducting properties added by adding impurities to the polysilicon. Alternatively, the gate electrodes 39A, 39B, and 39C may be formed using a metallic material, such as copper.

The n-type impurity regions 41A, 41B, 41C, 41D, and 41E are formed by doping n-type impurities, such as phosphorus (P), into the semiconductor substrate 31 by ion implantation. In the example illustrated in FIG. 2, the n-type impurity region 41D is shared by the amplifier transistor 11 and the address transistor 13. As a result, the amplifier transistor 11 and the address transistor 13 are connected in series. The n-type impurity region 41D may be separated into two n-type impurity regions. The two n-type impurity regions may be electrically connected via a wiring layer.

In the semiconductor substrate 31, an element separation region 42 is provided between the pixels 110 adjacent to each other and between the amplifier transistor 11 and the reset transistor 12. The element separation region 42 electrically separates the adjacent pixels 110 from each other. In addition, the element separation region 42 reduces leakage of signal charge stored in the charge storage node 24. The element separation region 42 is formed by, for example, doping high-concentration p-type impurities into the semiconductor substrate 31.

A multilayer wiring structure is provided on the top surface of the semiconductor substrate 31. The multilayer wiring structure includes a plurality of interlayer insulating layers, one or more wiring layers, one or more plugs, and one or more contact plugs. More specifically, an interlayer insulating layer 43 is stacked on the top surface of the semiconductor substrate 31. The interlayer insulating layer 43 is an example of an intermediate layer. The interlayer insulating layer 43 is, for example, a silicon oxide film, a silicon nitride film, or a tetraethyl orthosilicate (TEOS) film. Contact plugs 45A and 45B, conductive lines 46A and 46B, and conductive plugs 47A and 47B are buried in the interlayer insulating layer 43. The interlayer insulating layer 43 is formed by stacking a plurality of insulating layers in sequence. The top surface of the interlayer insulating layer 43 is, for example, flat and parallel to the top surface of the semiconductor substrate 31.

The contact plug 45A is connected to the n-type impurity region 41B of the reset transistor 12. The contact plug 45B is connected to the gate electrode 39B of the amplifier transistor 11. The conductive line 46A connects the contact plug 45A to the contact plug 45B. As a result, the n-type impurity region 41B of the reset transistor 12 is electrically connected to the gate electrode 39B of the amplifier transistor 11.

The conductive line 46A is connected to the pixel electrode 50 via the conductive plugs 47A and 47B and the conductive line 46B. Thus, the n-type impurity region 41B, the gate electrode 39B, the contact plugs 45A and 45B, the conductive lines 46A and 46B, the conductive plugs 47A and 47B, and the pixel electrode 50 constitute the charge storage node 24.

The photodetector 10 is provided on the interlayer insulating layer 43. The photodetector 10 includes the transparent electrode 52, the photoelectric conversion film 51, and the pixel electrode 50 that is located closer to the semiconductor substrate 31 than the transparent electrode 52.

The photoelectric conversion film 51 converts light incident from the side adjacent to the transparent electrode 52 to generate signal charge corresponding to the intensity of the incident light. The photoelectric conversion film 51 is composed of an organic semiconductor, for example. The photoelectric conversion film 51 may include one or more organic semiconductor layers. For example, in addition to the photoelectric conversion layer that generates hole-electron pairs, the photoelectric conversion film 51 may include a carrier transport layer that transports electrons or holes and a blocking layer that blocks carriers. Well-known organic p-type and organic n-type semiconductors can be used for the materials of the organic semiconductor layers. The photoelectric conversion film 51 may be, for example, a mixed film of organic donor molecules and acceptor molecules, a mixed film of semiconducting carbon nanotubes and acceptor molecules, or a film containing quantum dots. The photoelectric conversion film 51 may be formed using an inorganic material, such as amorphous silicon.

The photoelectric conversion film 51 is sandwiched between the transparent electrode 52 and the pixel electrode 50. According to the present embodiment, the photoelectric conversion film 51 is continuously formed over the plurality of pixels 110. More specifically, the photoelectric conversion film 51 is formed as a single flat plate to cover most of the imaging region in plan view. The photoelectric conversion film 51 may be provided separately for each of the pixels 110.

The transparent electrode 52 is an example of an upper electrode located at a higher position than the photoelectric conversion film 51. The transparent electrode 52 is formed using a material that is transparent to the light to be detected and that is electrically conductive. For example, the transparent electrode 52 is formed using a transparent conductive semiconductor oxide film, such as indium tin oxide (ITO), aluminum-doped zinc oxide (AZO), or gallium-doped zinc oxide (GZO). The transparent electrode 52 may be formed using another type of transparent conductive semiconductor or a thin metal film that is thin enough to transmit light.

Like the photoelectric conversion film 51, the transparent electrode 52 is formed continuously over the plurality of pixels 110. More specifically, the transparent electrode 52 is formed as a single flat plate to cover most of the imaging region in plan view. The transparent electrode 52 continuously covers the entire top surface of the photoelectric conversion film 51.

The pixel electrode 50 is an example of a lower electrode facing the upper electrode with the photoelectric conversion film 51 therebetween. The pixel electrode 50 is provided for each of the pixels 110. The pixel electrodes 50 are formed of a conductive material, such as a metal (for example, aluminum or copper), a metal nitride (for example, titanium nitride or tantalum nitride), or polysilicon that is doped with impurities to have conducting properties.

The photodetector 10 further includes an insulating layer 53 formed on at least part of the top surface of the transparent electrode 52. The photodetector 10 still further includes a protective film 54. The insulating layer 53 is formed so as to cover at least part of the top surface of the transparent electrode 52. The protective film 54 is provided at a higher position than the insulating layer 53.

The insulating layer 53 and the protective film 54 are formed of an insulating material. For example, the insulating layer 53 is formed of silicon oxide, silicon nitride, silicon oxynitride, or an organic or inorganic polymer material. The insulating layer 53 and the protective film 54 are, for example, transparent to light of a wavelength to be detected by the imaging device 100.

As illustrated in FIG. 2, the pixel 110 includes a color filter 55 at a higher position than the transparent electrode 52 of the photodetector 10. Furthermore, the pixel 110 includes a microlens 56 on the color filter 55. The pixel 110 need not necessarily include the insulating layer 53, the protective film 54, the color filter 55, and the microlens 56.

### Structure of End of Imaging Device

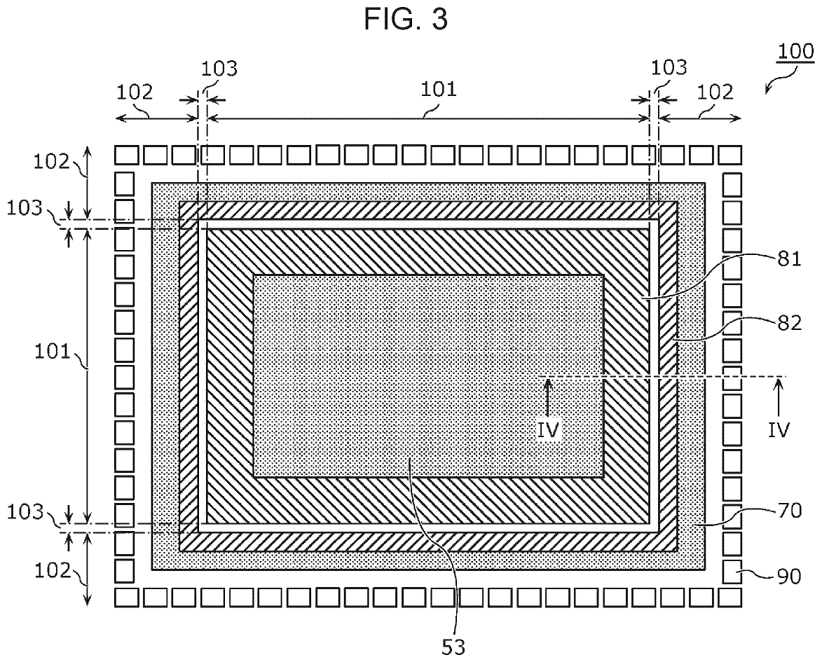

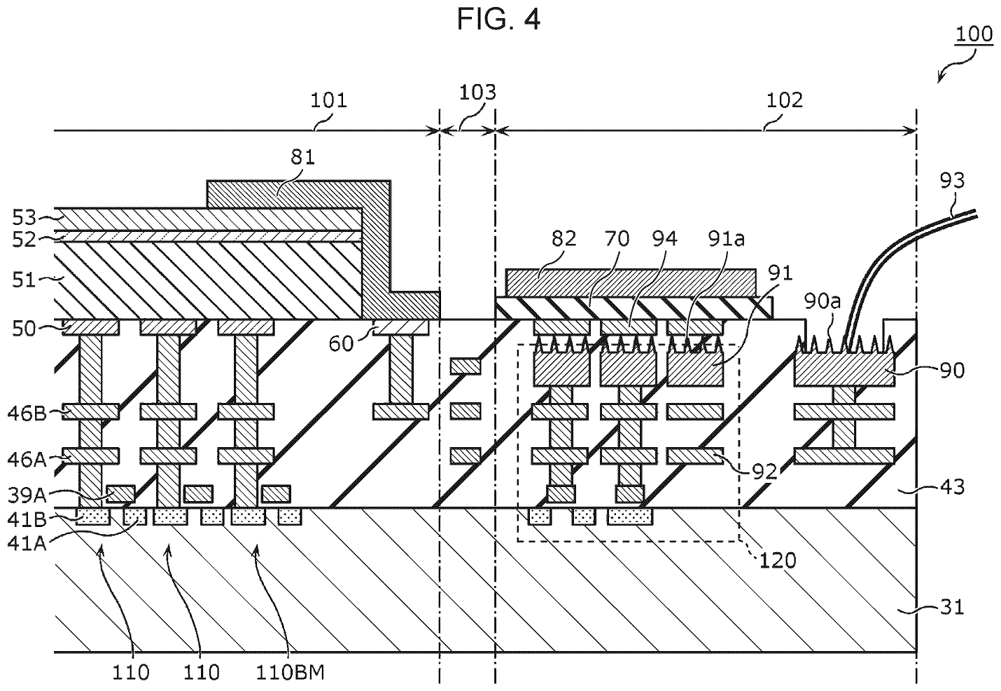

The structure of the end of the imaging device 100 is described below with reference to FIGS. 3 and 4.

FIG. 3 is a plane view of the imaging device 100. FIG. 4 is a cross-sectional view of the imaging device 100 taken along a line IV-IV of FIG. 3.

As illustrated in FIGS. 3 and 4, the imaging device 100 includes a pixel section 101 and a peripheral circuit section 102 provided around the pixel section 101. The imaging device 100 further includes a separation section 103 that separates the pixel section 101 from the peripheral circuit section 102.

In FIGS. 3 and 4, the protective film 54, the color filter 55, and the microlens 56 illustrated in FIG. 2 are not illustrated. The protective film 54 is provided, for example, to cover the insulating layer 53, a first light-shielding film 81, a second light-shielding film 82, and an insulating layer 70. The color filter 55 and microlens 56 are each provided directly above the pixel 110. The color filter 55 and the microlens 56 are not provided directly above the first light-shielding film 81 and in the separation section 103 and the peripheral circuit section 102.

The pixel section 101 is located in the center of the imaging device 100 in plan view and corresponds to the pixel region in which a plurality of pixels 110 are arranged. The peripheral circuit section 102 is provided in a ring shape around the pixel section 101. Therefore, the separation section 103 is also provided in a ring shape so as to surround the pixel section 101. The separation section 103 is a ring-shaped region located between the pixel section 101 and the peripheral circuit section 102.

The peripheral circuit section 102 may be provided only along part of the periphery of the pixel section 101. For example, in the case of the pixel section 101 having a rectangular shape in plan view as illustrated in FIG. 3, the peripheral circuit section 102 need not be provided in a region along at least one side of the contour of the pixel section 101. For example, the peripheral circuit section 102 may be provided in a region along only one side of the contour of the pixel section 101. Alternatively, the peripheral circuit section 102 may be provided in regions along two opposing or neighboring sides of the contour of the pixel section 101. The same applies to the separation section 103.

### Light-Shielding Film

As illustrated in FIGS. 3 and 4, the pixel section 101 includes the first light-shielding film 81. The first light-shielding film 81 provides two functions: feeding power to the transparent electrode 52 and shielding a pixel 110BM from light.

More specifically, the first light-shielding film 81 has conducting properties and is electrically connected to the transparent electrode 52. According to the present embodiment, as illustrated in FIG. 4, the first light-shielding film 81 is in contact with an end surface of the transparent electrode 52.

The first light-shielding film 81 is electrically connected to an electrode terminal 60, which is exposed on the top surface of the interlayer insulating layer 43. The electrode terminal 60 is electrically connected to the counter electrode signal line 16 (refer to FIG. 1) inside the interlayer insulating layer 43. As a result, the transparent electrode 52 is electrically connected to the voltage control circuit 30 via the first light-shielding film 81, the electrode terminal 60, and the counter electrode signal line 16 (refer to FIG. 1). That is, the first light-shielding film 81 constitutes part of electrical wiring for applying a predetermined voltage to the transparent electrode 52. The predetermined voltage is applied to the first light-shielding film 81, and the value of the voltage may vary according to the operating state of the imaging device 100. That is, a variable voltage is applied to the first light-shielding film 81. The variable voltage includes, for example, a first voltage that is applied during exposure and a second voltage that is applied during pixel readout. The first voltage and the second voltage are selectively applied to the transparent electrode 52 via the first light-shielding film 81 according to the operating state of the imaging device 100.

The first light-shielding film 81 covers the pixels 110BM, which are some of the plurality of pixels 110 included in the pixel section 101. The pixels 110BM are pixel for black correction processing performed by the imaging device 100 and are covered by the first light-shielding film 81 to prevent light from entering the pixels 110BM. More specifically, the first light-shielding film 81 overlaps part of the top surface of the photoelectric conversion film 51 in plan view.

As illustrated in FIG. 3, the first light-shielding film 81 is, for example, annularly provided along the outer periphery of the pixel section 101 in plan view. A region on the inner side of the inner periphery of the first light-shielding film 81 is the photosensitive region. That is, photoelectric conversion is performed by the plurality of pixels 110 disposed on the inner side of the inner periphery of the first light-shielding film 81 in plan view, and imaging is performed on the basis of the generated signal charge.

As illustrated in FIGS. 3 and 4, the peripheral circuit section 102 includes the second light-shielding film 82. The second light-shielding film 82 overlaps at least part of the peripheral circuitry 120 in plan view. More specifically, the second light-shielding film 82 overlaps, in plan view, a sample hold circuit (not illustrated in FIG. 4) included in the peripheral circuitry 120. The second light-shielding film 82 may also overlap, in plan view, a transistor or a diode included in a circuit other than the sample hold circuit included in the peripheral circuitry 120.

Transistors in sample hold circuits and the like have an impurity region formed in the semiconductor substrate 31 as a source or a drain. Since the impurity region is an n-type impurity region formed in the p-type semiconductor substrate 31, a pn junction is formed at the boundary of the impurity region. Similarly, a diode in the sample hold circuit has a pn junction.

If light is incident on the pn junction, the incident light generates electric charge, and the generated charge may cause a leakage current or potential fluctuation. In particular, since the sample hold circuit temporarily holds the signal charge generated in the pixel 110, the generation of a charge other than the signal charge in the sample hold circuit may degrade the image quality of an image generated by the imaging device 100.

According to the present embodiment, the transistor and diode are covered by the second light-shielding film 82, which prevents light from entering the pn junction. This enables the peripheral circuitry 120 to operate stably. In addition, since generation of charges other than signal charge due to light in the sample hold circuit can be prevented, degradation of image quality can be prevented.

As illustrated in FIG. 3, the second light-shielding film 82 is provided annularly along the inner periphery of the peripheral circuit section 102 in plan view. The shape of the second light-shielding film 82 in plan view does not have to be a ring shape, but may be a long rectangle along one side of the inner periphery of the peripheral circuit section 102 or an L-shape along two sides.

The first light-shielding film 81 and the second light-shielding film 82 are formed of, for example, the same material. Therefore, like the first light-shielding film 81, the second light-shielding film 82 has conducting properties. The first light-shielding film 81 and the second light-shielding film 82 are, for example, metal films, such as titanium (Ti) or molybdenum (Mo), or metal nitride films, such as titanium nitride (TiN) or tantalum nitride (TaN).

According to the present embodiment, as illustrated in FIG. 4, the peripheral circuit section 102 further includes the insulating layer 70. The second light-shielding film 82 is provided at a higher position than the insulating layer 70. More specifically, the second light-shielding film 82 is located at a higher position than the top surface of the interlayer insulating layer 43 and is located at a higher position than at least the bottom surface of the photoelectric conversion film 51. According to the present embodiment, the second light-shielding film 82 is provided so as to be in contact with the top surface of the insulating layer 70.

The insulating layer 70 is an insulating layer located between the second light-shielding film 82 and the interlayer insulating layer 43. The insulating layer 70 overlaps the top surface of the interlayer insulating layer 43 in plan view. As a result, even when part of the wiring structure is exposed on the top surface of the interlayer insulating layer 43, it can be prevented that the exposed part of the wiring structure is brought into contact with the second light-shielding film 82 and, thus, electrical connection therebetween occurs.

The insulating layer 70 is formed of, for example, the same material as the insulating layer 53. For this reason, the insulating layer 70 has the same translucency as the insulating layer 53. More specifically, the insulating layer 70 is, for example, a silicon oxide film, a silicon nitride film, or a tetraethyl orthosilicate (TEOS) film. The insulating layer 70 can be formed by the same process as the insulating layer 53. For example, after patterning the photoelectric conversion film 51 and transparent electrode 52 to a predetermined shape, an insulating film is formed on the entire surface including the top surface of the transparent electrode 52, and patterning is performed by photolithography and etching, so that the insulating layer 53 and insulating layer 70 can be simultaneously formed. As a result, the thickness of the insulating layer 70 is the same as that of the insulating layer 53. However, the insulating layer 70 may be formed using a material that have no translucency.

According to the present embodiment, the first light-shielding film 81 and the second light-shielding film 82 can be formed by the same process. For example, after the insulating layer 53 and the insulating layer 70 are formed, a conductive light-shielding film is formed so as to cover the top surfaces of the insulating layer 53 and the insulating layer 70. Thereafter, patterning is performed by photolithography and etching. Thus, the first light-shielding film 81 and the second light-shielding film 82 can be simultaneously formed. As a result, the thickness of the first light-shielding film 81 is the same as that of the second light-shielding film 82.

As illustrated in FIGS. 3 and 4, the first light-shielding film 81 and the second light-shielding film 82 are separated. That is, the first light-shielding film 81 and the second light-shielding film 82 are not physically connected. The separation section 103 is included between the first light-shielding film 81 and the second light-shielding film 82 in plan view. The separation section 103 is, for example, a region between the outer periphery of the first light-shielding film 81 and the insulating layer 70. For convenience of illustration, FIG. 3 illustrates an example in which the inner periphery of the insulating layer 70 and the inner periphery of the second light-shielding film 82 are coincident. However, as illustrated in FIG. 4, the second light-shielding film 82 is provided on the outer side of the inner periphery of the insulating layer 70.

Alternatively, as illustrated in FIG. 3, the inner periphery of the second light-shielding film 82 may coincide with the inner periphery of the insulating layer 70. That is, the separation section 103 may be a region between the outer periphery of the first light-shielding film 81 and the inner periphery of the second light-shielding film 82. For example, if the insulating layer 70 is not provided, the separation section 103 corresponds to a region between the outer periphery of the first light-shielding film 81 and the inner periphery of the second light-shielding film 82.

Since the first light-shielding film 81 and the second light-shielding film 82 are separated, fluctuations in the potential of the first light-shielding film 81 have little effect on the second light-shielding film 82. That is, even if the potential of the first light-shielding film 81 fluctuates, the potential of the second light-shielding film 82 is kept constant, so that the effect on the peripheral circuitry 120 covered by the second light-shielding film 82 is also sufficiently reduced. Therefore, according to the present embodiment, the peripheral circuitry 120 can be operated stably regardless of fluctuations in the potential of the first light-shielding film 81.

### Pad

As illustrated in FIGS. 3 and 4, the peripheral circuit section 102 includes one or more pads 90. More specifically, the plurality of pads 90 are disposed in an annular arrangement along the outer periphery of the imaging device 100. The imaging device 100 is a chip component having a rectangular shape in plan view.

The pad 90 contains aluminum (Al). The pad 90 is an electrode portion on which wire bonding is to be performed. A thin metal wire 93 is brought into pressure contact with the pad 90, and the thin metal wire 93 and the pad 90 are bonded by applied ultrasonic vibration. Thus, the pad 90 and an electrode of a package or a printed circuit board can be electrically connected. A signal is retrieved from the imaging device 100 to the outside, or power potential is supplied to the imaging device 100 through the pad 90. For example, the pad 90 is provided to supply potential to the transparent electrode 52. Although not illustrated in FIG. 4, the pad 90 is connected to the electrode terminal 60 via a conductive line 91 or 92 and is connected to the transparent electrode 52 via the first light-shielding film 81.

The smaller size of pad 90 allows for smaller and thinner equipment set including the imaging device 100. The small area of pad 90 is achieved by using ultrasonic bonding technique to bond a wire to an electrode. For example, a gold wire with a diameter of several tens of microns can be used for the thin metal wire 93.

However, in widely used semiconductor devices, there is a risk that the bonding between the pad 90 and the thin metal wire 93 is insufficient and, thus, the thin metal wire 93 may come off over time. Alternatively, bonding may fail during a wedge bonding process, resulting in a failure to provide a stable current supply. To prevent the failure, it is effective to increase the contact area between the pad 90 and the thin metal wire 93. As illustrated in FIG. 4, in the imaging device 100 according to the present embodiment, the surface of the pad 90 has minute irregularities 90a formed thereon.

The irregularities 90a are microscopic bumps and dips called hillocks. When aluminum in the pad 90 is heated to near its melting point to promote crystal growth, the microscopic bumps and dips called hillocks appear. By actively generating hillocks, the irregularities 90a are formed on the surface of the pad 90, which can increase the bonding force of the thin metal wire 93 described above. More specifically, after depositing a film using aluminum as the material of the pad 90, an annealing process is introduced to actively promote the growth of hillocks. The annealing process is performed, for example, before the photoelectric conversion film 51 is formed.

The bonding strength can be measured experimentally by pulling the thin metal wire 93 and peeling it from the pad 90. If the bonding strength is high to a certain extent, the bonding strength can withstand the stress applied in subsequent processes and the tensile strength caused by the difference in linear expansion coefficient due to various environmental temperature changes. For example, a surface roughness Ra of the pad 90 is greater than or equal to 150 nm. The arithmetic average roughness Ra, which represents the surface roughness, can be measured with, for example, a contact-type roughness meter.

In terms of the growth of hillocks, the crystal growth increases with increasing volume of aluminum and, thus, the surface irregularities increase. For this reason, the pad 90 is formed so that the film thickness of the pad 90 is greater than that of another conductive line, for example. In addition, a large amount of energy is supplied to the pad 90 when the pad 90 and the thin metal wire 93 are ultrasonic bonded. To prevent the pad 90 from changing its shape (for example, peeling, alteration, bending, or partial loss) due to the energy, the pad 90 is formed so as to be thick. For example, the thickness of the pad 90 is greater than or equal to 500 nm.

### Conductive Lines

According to the present embodiment, as illustrated in FIG. 4, the peripheral circuit section 102 includes the conductive line 91 and the conductive line 92. The peripheral circuit section 102 includes a plurality of conductive lines 91 and a plurality of conductive lines 92.

The conductive line 91 is an example of a first conductive line. The conductive line 91 is located inside of the interlayer insulating layer 43 and contains aluminum (Al). More specifically, the conductive line 91 is located in the same layer as the pad 90 and is formed using the same material as the pad 90. That is, the conductive line 91 and the pad 90 can be formed by the same process. Therefore, the thickness of the conductive line 91 is the same as that of the pad 90. For example, the thickness of the conductive line 91 is greater than or equal to 500 nm.

The plurality of conductive lines 91 are set to, for example, different potentials or are used to transmit different signals from each other. For this reason, the plurality of conductive lines 91 are separated in plan view so as not to short-circuit each other.

The conductive line 92 is an example of the second conductive line. The conductive line 92 contains copper (Cu). The conductive line 92 is located inside of the interlayer insulating layer 43. More specifically, the conductive line 92 is located in the same layer as the conductive line 46A or 46B provided in the pixel section 101 and is formed of the same material. That is, the conductive line 92 and the conductive line 46A or 46B can be formed by the same process. Therefore, the thickness of the conductive line 92 is the same as that of the conductive line 46A or 46B.

In image sensors, such as the imaging device 100, the pixel size has been reduced, the area of the peripheral circuit section 102 has been reduced, and the conductive lines have been miniaturized in order to reduce the size of the image sensor. For example, in image sensors mounted in smartphones, the pixel size is on the order of submicron. In this case, to pass a plurality of different potential conductive lines in each pixel, it is common for the line width of the conductive lines 46A and 46B to be about 20 nm to about 50 nm. Similarly, in the peripheral circuit section 102, the line width of the conductive line 92 is substantially the same as that of the conductive lines 46A and 46B in the pixel section 101.

The formation process for the conductive lines 46A, 46B, and 92 employs a method called dual damascene, in which plating and a planarization process are performed in combination. However, this method cannot form a conductive line with a large aspect ratio. As used herein, the term “aspect ratio” refers to the ratio of the thickness to the width of the conductive line in the cross section perpendicular to the direction in which the conductive line extends. The aspect ratio of the conductive line formed by the method is about 3 at most. Therefore, the maximum thickness of the conductive lines 46A, 46B, and 92 is 3×50 nm=150 nm. That is, it can be seen that the thickness of the conductive line 92 is inevitably less than or equal to ⅓ of the thickness of the conductive line 91. This means that the resistance of the conductive line 92 is three times the resistance of the conductive line 91.

To supply power from the pad 90 to the pixel section 101 through the peripheral circuit section 102 or to read out a signal from each of the pixels, it is advantageous to use a conductive line with the minimized resistance. Therefore, in the peripheral circuit section 102, the use of the conductive line 91 containing aluminum as a signal line and a conductive line for supplying potential achieves an effect of reducing power consumption or the like.

### Barrier Layer

According to the present embodiment, as illustrated in FIG. 4, the peripheral circuit section 102 includes a barrier layer 94. The barrier layer 94 is provided to avoid contact between the conductive line 91 and the second light-shielding film 82.

As described above, the peripheral circuit section 102 includes the second light-shielding film 82 for shielding the peripheral circuitry 120 from light. In general, the peripheral circuit section 102 does not include an optical lens or a microlens to collect light. Therefore, the ambient light that is the target to be prevented from entering the peripheral circuitry 120 may be incident from random directions. To reduce the obliquely incident light, the second light-shielding film 82 may be made larger with a margin for a transistor portion including the pn junction.

However, by reducing the area of the second light-shielding film 82, the need for miniaturization of the imaging device 100 can be met. In this case, the distance between the surface of the semiconductor substrate 31 having the pn junction provided thereon and the second light-shielding film 82 can be, for example, less than or equal to 5 μm. In plan view, the second light-shielding film 82 covers the pn junction with a margin of greater than or equal to 50 μm, for example. This enables the second light-shielding film 82 to block the ambient light and prevent the ambient light from entering the pn junction.

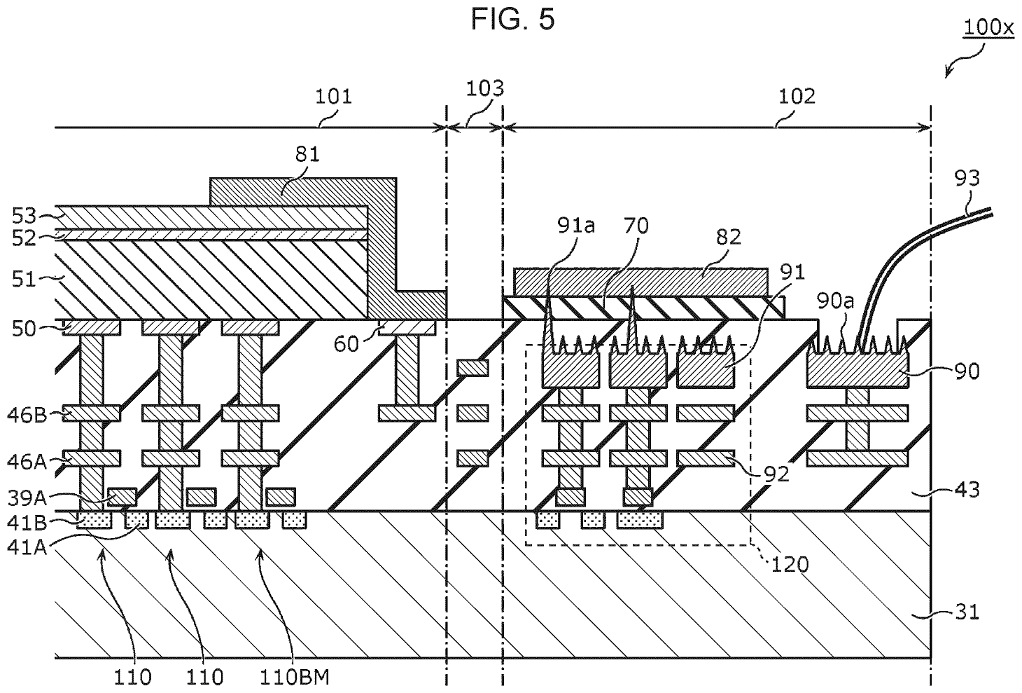

Thus, the second light-shielding film 82 provided in the peripheral circuit section 102 is disposed at a position not so far from the surface of the semiconductor substrate 31. In this case, as illustrated in FIG. 5, there is a risk of physical contact and electrical connection between the conductive line 91 and the second light-shielding film 82. FIG. 5 is a cross-sectional view of an imaging device 100x according to a comparative example. In the imaging device 100x according to the comparative example, the barrier layer 94 is not provided.

The conductive line 91 is formed by the same process as the pad 90. Therefore, like the surface of the pad 90, the surface of the conductive line 91 has irregularities 91a formed thereon. If, as illustrated in FIG. 5, the barrier layer 94 is not provided, the growth of hillocks may be promoted and, thus, the irregularities 91a may be brought into contact with the second light-shielding film 82. The closer the second light-shielding film 82 is to the semiconductor substrate 31, the greater the probability of contact between the irregularities 91a and the second light-shielding film 82.

As described above, the growth of hillocks is performed by the annealing process, prior to the formation of the photoelectric conversion film 51 and the second light-shielding film 82. Therefore, at the time when the irregularities 91a are formed, the second light-shielding film 82 has not yet been formed. By forming the insulating layer 70 before the second light-shielding film 82 is formed, contact between the irregularities 91a and the second light-shielding film 82 can be avoided.

However, besides the growth of hillocks due to the annealing process, the irregularities 91a may be formed due to the occurrence of migration phenomena even in a room temperature environment. That is, even after the insulating layer 70 and the second light-shielding film 82 are formed, there is a risk that the irregularities 91a may be formed so as to penetrate the insulating layer 70 and, thus, the irregularities 91a and the second light-shielding film 82 may be brought into contact. For this reason, simply providing the insulating layer 70 is not sufficient.

The occurrence of the contact also depends on the thickness of the insulating film formed on the conductive line 91. In general, in image sensors, a material with a low dielectric constant, called a low-k material, is used as the insulating film material in order to reduce the parasitic capacitance between the conductive lines and to maximally reduce noise. Candidates for the insulating film material include Spin-on Glass materials or organic insulating materials. In addition, TEOS materials are often used as materials that satisfy reliability tests for adhesiveness and a dielectric breakdown voltage to withstand the subsequent CMP (Chemical Mechanical Polishing) process.

In general, insulating films formed using these low-k materials have a low elastic modulus and a sparse film quality. Therefore, the insulating films do not have such a hardness that prevents hillocks of aluminum contained in the conductive line 91.

Therefore, there is a risk of electrical connection due to physical contact between the plurality of conductive lines 91 and the second light-shielding film 82. In this case, the plurality of conductive lines 91, which are originally provided to supply different potentials, may short-circuit each other, resulting in a failure to maintain the desired signal characteristics.

In contrast, in the imaging device 100 according to the present embodiment, a barrier layer 94 is located between the conductive line 91 and the second light-shielding film 82, as illustrated in FIG. 4. The insulating layer 70 is disposed between the barrier layer 94 and the second light-shielding film 82. That is, the barrier layer 94 is not in contact with the second light-shielding film 82. The barrier layer 94 blocks the growth of the irregularities 91a on the surface of the conductive line 91.

The barrier layer 94 contains a metal that is harder than aluminum and that has a higher melting point than aluminum. More specifically, the barrier layer 94 contains a metal that has a higher modulus of elasticity than aluminum. Still more specifically, the barrier layer 94 contains a high melting point material, such as titanium (Ti), molybdenum (Mo), tantalum (Ta), or tungsten (W). For example, the barrier layer 94 is a metal layer containing at least one of Ti, Mo, Ta, and W. The materials are often also used for a metal barrier layer or a contact via layer for conductive lines and are suitable for a semiconductor process.

The barrier layer 94 that is made of metal has conducting properties. In this case, the barrier layer 94 is provided for each of the conductive lines 91. That is, the peripheral circuit section 102 includes a plurality of barrier layers 94. The plurality of barrier layers 94 are disposed so as to be separated from each other. Each of the plurality of barrier layers 94 is aligned with a corresponding one of the plurality of conductive lines 91 in plan view. The width of the barrier layer 94 is, for example, the same as the width of the conductive line 91 in plan view. As used herein, the term “width” refers to the length in a direction parallel to the principal surface of the semiconductor substrate 31 in a cross section perpendicular to the direction in which the conductive line 91 extends. As a result, the contact between the irregularities 91a of the conductive line 91 and the second light-shielding film 82 can be prevented while ensuring a distance between adjacent barrier layers 94.

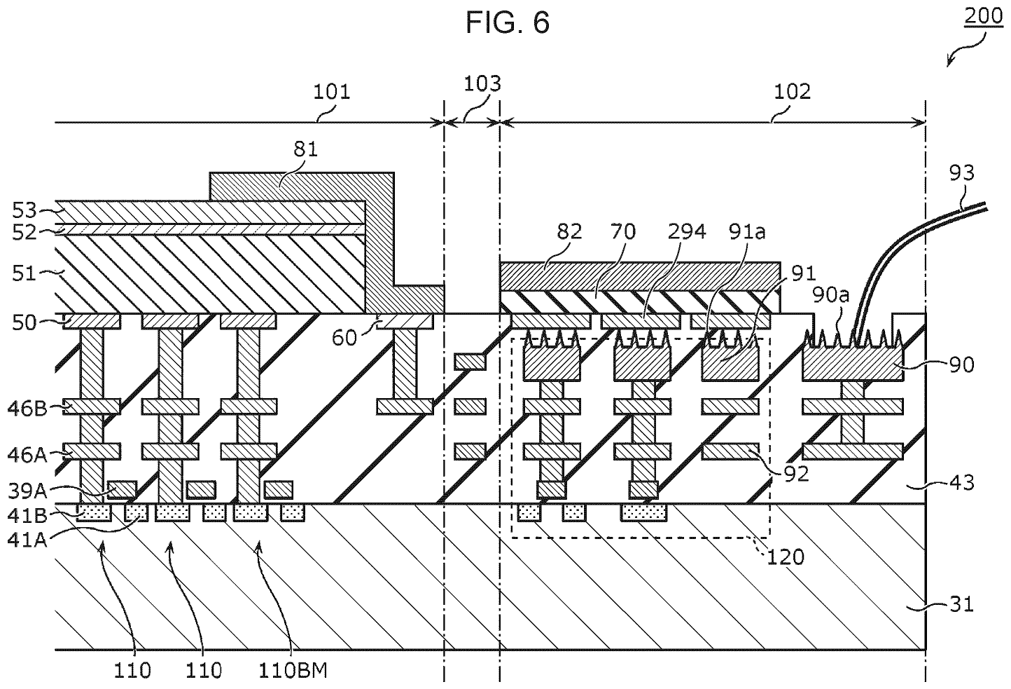

The width of the barrier layer 94 may be greater than the width of the conductive line 91. FIG. 6 is a cross-sectional view of an imaging device 200 according to a modification of the present embodiment. As illustrated in FIG. 6, unlike the imaging device 100 illustrated in FIG. 4, the imaging device 200 includes a barrier layer 294 instead of the barrier layer 94.

The width of the barrier layer 294 is greater than the width of the conductive line 91 in plan view. For example, as viewed in plan view, the barrier layer 294 completely covers the conductive line 91. This can prevent the growth of the irregularities 91a on the surface of the conductive line 91 and can more strongly prevent physical contact between the second light-shielding film 82 and the conductive line 91.

As described above, in the imaging device 100 according to the present embodiment, the barrier layer 94 is provided between the conductive line 91 and the second light-shielding film 82. The barrier layer 94 can block the growth of the irregularities 91a on the surface of the conductive line 91 and prevent physical contact between the conductive line 91 and the second light-shielding film 82. Electrical connection between the second light-shielding film 82 and the conductive line 91 and between the conductive lines 91 via the second light-shielding film 82 can be prevented. As a result, the potential or the signal characteristics of the conductive line 91 can be maintained and, thus, the circuit operation performed by the imaging device 100 can be stabilized.

### SECOND EMBODIMENT

The second embodiment is described below.

In the imaging device according to the second embodiment, the position of the barrier layer is different from that in the imaging device according to the first embodiment. Hereinafter, the differences from the first embodiment are mainly described, and description that is the same as in the first embodiment is omitted or simplified.

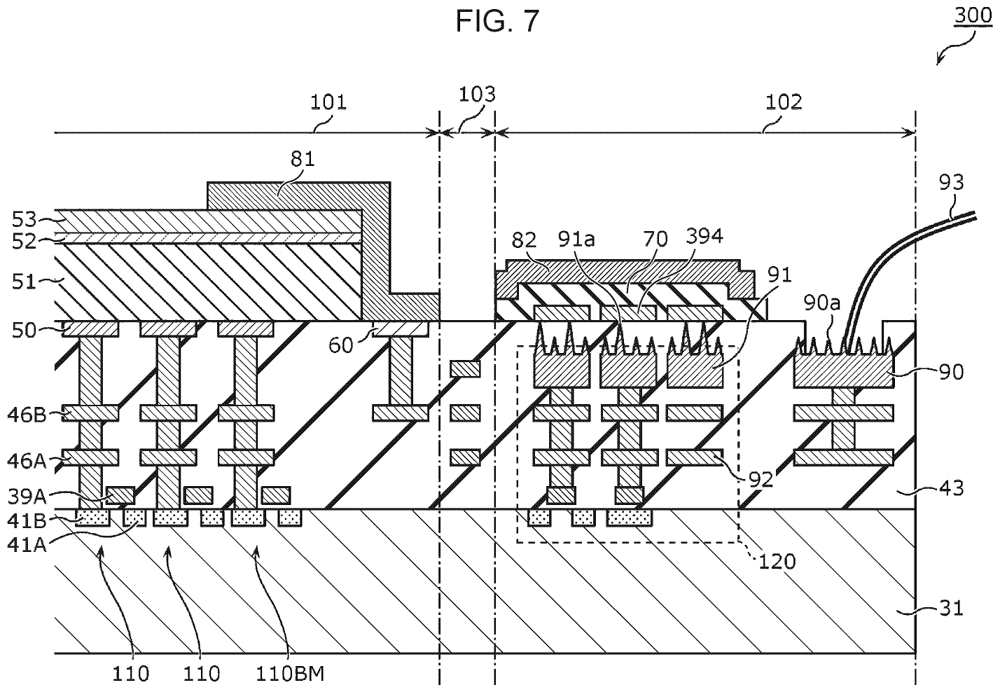

FIG. 7 is a cross-sectional view of an imaging device 300 according to the second embodiment. As illustrated in FIG. 7, unlike the imaging device 100 illustrated in FIG. 4, the imaging device 300 includes a barrier layer 394 instead of the barrier layer 94.

The barrier layer 394 is disposed on the top surface of the interlayer insulating layer 43. The top surface of the interlayer insulating layer 43 is flat in the pixel section 101 and the peripheral circuit section 102. Therefore, the bottom surface of the barrier layer 394 is at the same height from the semiconductor substrate 31 as the bottom surface of the photoelectric conversion film 51.

According to the second embodiment, the barrier layer 394 is formed by a different process than the pixel electrode 50. Therefore, the barrier layer 394 can be formed using a different material so as to have a different thickness than the pixel electrode 50. In this case, the barrier layer 394 is not required to have particular electrical and optical characteristics. That is, the barrier layer 394 may have insulation properties or translucency. For example, the barrier layer 394 may be an oxide or nitride, such as Ti, Ta, or W.

When the barrier layer 394 has insulation properties, the barrier layer 394 need not be separated for each of the conductive lines 91. That is, one barrier layer 394 may be provided to cover all of the plurality of conductive lines 91.

### THIRD EMBODIMENT

The third embodiment is described below.

Unlike the imaging device according to the first embodiment, in an imaging device according to the third embodiment, a barrier layer has insulation properties. Hereinafter, the differences from the first embodiment are mainly described, and description that is the same as in the first embodiment is omitted or simplified.

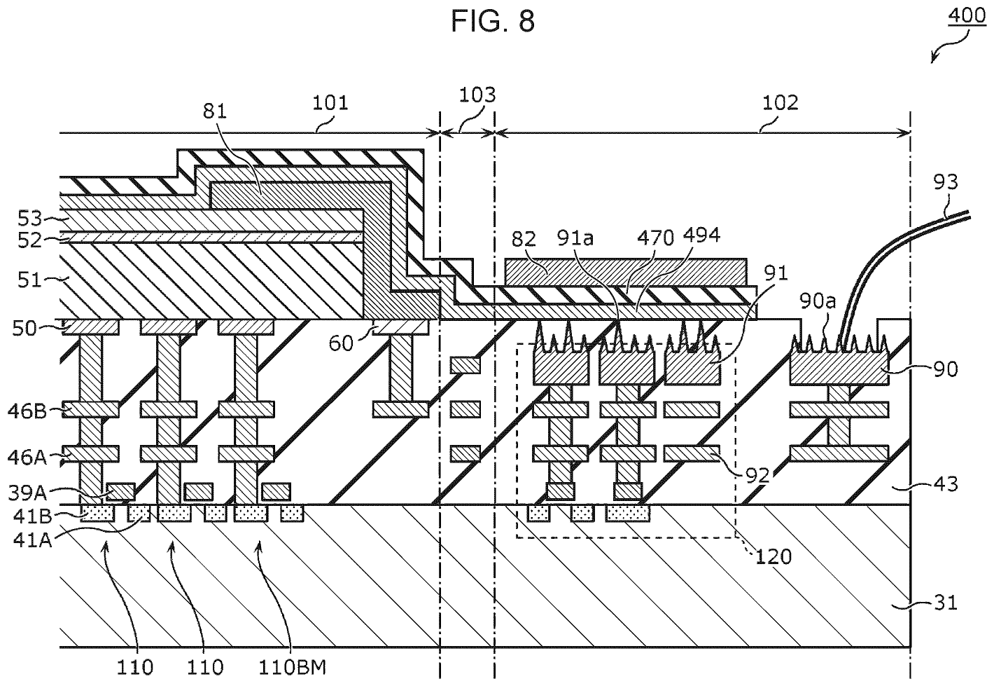

FIG. 8 is a cross-sectional view of an imaging device 400 according to the third embodiment. As illustrated in FIG. 8, unlike the imaging device 100 illustrated in FIG. 4, the imaging device 400 includes an insulating layer 470 and a barrier layer 494 instead of the insulating layer 70 and the barrier layer 94.

If the barrier layer 494 is a film with a dense film quality, a hillock can be prevented without using a special high melting point material. According to the third embodiment, the film density of the barrier layer 494 is greater than that of the interlayer insulating layer 43.

The atomic layer deposition (ALD) method can be used as a technique to form a barrier layer 494 with dense film quality. According to the ALD method, the deposition rate is slow because a film is deposited every several atomic layers, but a dense film with high crystallinity and low gas permeability is formed.

The barrier layer 494 is an insulating film formed of a material different from that of the interlayer insulating layer 43 and the insulating layer 470. For example, the barrier layer 494 is an aluminum oxide film formed by the ALD method. An aluminum oxide film has insulation properties and is used as a passivation film for an organic semiconductor material contained in the photoelectric conversion film 51. Therefore, the barrier layer 494 is provided not only in the peripheral circuit section 102 but also in the pixel section 101 and the separation section 103. For example, the barrier layer 494 is provided in a substantially entire region of the imaging device 400 (for example, the entire region excluding the pad 90 and its vicinity).

According to the third embodiment, like the barrier layer 494, the insulating layer 470 is provided over almost the entire region of the imaging device 400. The insulating layer 470 is a protective insulating layer, such as a silicon oxide film or a silicon nitride film.

The insulating layer 470 need not be provided. That is, the second light-shielding film 82 may be provided so as to be in contact with the top surface of the barrier layer 494. Since the barrier layer 494 has insulation properties, electrical connection between the conductive line 91 and the second light-shielding film 82 can be prevented even if the barrier layer 494 and the second light-shielding film 82 are in contact with each other.

As described above, according to the imaging device 400 of the third embodiment, the barrier layer 494 can be used not only to prevent aluminum growth but also as a passivation film to improve the reliability of the photoelectric conversion film 51. More specifically, since the blocking function and the protection function can be provided by a single barrier layer 494, the process can be simplified as compared with the case where the films are formed separately.

The second light-shielding film 82 is formed after the barrier layer 494 and the insulating layer 470 are formed. Therefore, the second light-shielding film 82 is formed in a different process than the first light-shielding film 81. As a result, the second light-shielding film 82 can be formed using a different material than the first light-shielding film 81 and can have a different thickness than the first light-shielding film 81.

Any dense film can be used as the barrier layer 494, and the barrier layer 494 is not limited to an aluminum oxide film. The barrier layer 494 may be a silicon oxide film, a zirconium oxide film, or a hafnium oxide film. The barrier layer 494 may have a multilayer structure consisting of a plurality of insulating layers.

### OTHER EMBODIMENTS

While the imaging devices according to one or more aspects have been described with reference to the exemplary embodiments, the present disclosure is not limited to the exemplary embodiments. Embodiments subjected to a variety of modifications that those skilled in the art can conceive without departing from the scope and spirit of the present disclosure and embodiments achieved by combining the constituent elements of different embodiments are also encompassed within the scope of the present disclosure.

For example, the width of the barrier layer 94 may be less than the width of the conductive line 91. When the spacing between the conductive lines 91 is small, there is a risk that the adjacent barrier layers 94 may be brought into contact with each other. By making the width of the barrier layer 94 less than the width of the conductive line 91, contact between the barrier layers 94 can be prevented, and electrical connection between the conductive lines 91 via the barrier layer 94 can be prevented. For example, a plurality of barrier layers 94 may be disposed for one conductive line 91. Although part of the surface of the conductive line 91 is not covered by the barrier layer 94 in plan view, the growth of the irregularities 91a can be reduced as compared with the case where the barrier layer 94 is not provided.

In addition, each of the above-described embodiments may be changed, replaced, added, omitted, or the like in various ways within the scope of the claims or their equivalents.

The present disclosure can be applied to an imaging device capable of stabilizing the circuit operation (for example, a camera or a distance measurement device).

What is claimed is:

1. An imaging device comprising:
a pixel section including pixels;
a peripheral circuit section that is provided around the pixel section and that includes a peripheral circuit; and
an intermediate layer that extends across the pixel section and the peripheral circuit section,
wherein the peripheral circuit section includes
a light-shielding film located above the intermediate layer,
at least one first conductive line that is located in the intermediate layer and that contains aluminum, and
at least one barrier layer located between the at least one first conductive line and the light-shielding film.

2. The imaging device according to claim 1, wherein
the pixel section includes
a photoelectric conversion film located above the intermediate layer, and
an upper electrode located above the photoelectric conversion film, and
the peripheral circuit section includes a pad that supplies a potential to the upper electrode.

3. The imaging device according to claim 2, wherein the pad and the at least one first conductive line are located in the same layer and are made of the same material.

4. The imaging device according to claim 2, wherein a surface roughness of each of the pad and the at least one first conductive line is greater than or equal to 150 nm.

5. The imaging device according to claim 1, wherein the at least one barrier layer contains a metal that is harder than aluminum and that has a melting point higher than a melting point of aluminum.

6. The imaging device according to claim 1, wherein the at least one barrier layer has conducting properties.

7. The imaging device according to claim 6, wherein
the at least one first conductive line comprises a plurality of first conductive lines,
the at least one barrier layer comprises a plurality of barrier layers,
the plurality of first conductive lines are disposed so as to be separated from each other in plan view,
the plurality of barrier layers are disposed so as to be separated from each other in plan view, and
each of the plurality of barrier layers is disposed so as to be aligned with a corresponding one of the plurality of first conductive lines.

8. The imaging device according to claim 1, wherein the at least one barrier layer has insulation properties.

9. The imaging device according to claim 8, wherein a film density of the at least one barrier layer is higher than a film density of the intermediate layer.

10. The imaging device according to claim 8, wherein
the intermediate layer includes a tetraethyl orthosilicate film, and
the at least one barrier layer includes an aluminum oxide film.

11. The imaging device according to claim 1, wherein a width of the at least one barrier layer is equal to or greater than a width of the at least one first conductive line in plan view.

12. The imaging device according to claim 1, further comprising:
a second conductive line that contains copper,
wherein a thickness of the at least one first conductive line is greater than a thickness of the second conductive line.

13. The imaging device according to claim 1, further comprising:
a substrate located below the intermediate layer,
wherein a distance between the light-shielding film and a surface of the substrate is less than 5 μm.

14. The imaging device according to claim 1, wherein the at least one barrier layer overlaps the at least one first conductive line in plan view.

15. The imaging device according to claim 1, wherein
the peripheral circuit section includes a sample hold circuit, and
the light-shielding film overlaps the sample hold circuit in plan view.

16. The imaging device according to claim 1, wherein the light-shielding film covers an entirety of the at least one first conductive line.

17. The imaging device according to claim 1, wherein the pixel section does not include a conductive line that contains aluminum.

18. The imaging device according to claim 1, wherein the peripheral circuit section further includes a pad that differs from the at least one first conductive line.

19. The imaging device according to claim 18, wherein the pad is provided in the same layer as the at least one first conductive line.
